(19) United States
(12) Patent Application Publication
(10) Pub. No.: US 2023/0260837 A1
(43) Pub. Date: Aug. 17, 2023

(54) METHODS TO IMPROVE WAFER WETTABILITY FOR PLATING - ENHANCEMENT THROUGH SENSORS AND CONTROL ALGORITHMS

(71) Applicant: Lam Research Corporation, Fremont, CA (US)

(72) Inventors: Hyungjun Hur, Richardson, TX (US); Pooja Tilak, Beaverton, OR (US); Shantinath Ghongadi, Tigard, OR (US); Cian Sweeney, Portland, OR (US)

(21) Appl. No.: 17/998,255

(22) PCT Filed: May 3, 2021
(86) PCT No.: PCT/US2021/030487

§ 371 Date: Nov. 8, 2022

Related U.S. Application Data
(60) Provisional application No. 63/022,473, filed on May 9, 2020.

(51) Int. Cl. H01L 21/768; C25D 7/12; C25D 17/00; C25D 21/12

(52) U.S. Cl. CPC H01L 21/76873; C25D 7/123; C25D 17/001; C25D 21/12; H01L 21/76861; H01L 21/76877

(57) ABSTRACT

Various embodiments include methods and apparatuses to moisturize a substrate prior to an electrochemical deposition process. In one embodiment, a method to control substrate wettability includes placing a substrate in a humidification environment, controlling the humidification environment to moisturize a surface of the substrate; and placing the substrate into a plating cell. Other methods and systems are disclosed.

### INCORPORATED BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor devices may be formed in a multi-level arrangement with electrically conductive material deposited in trenches and/or holes to form vias, contacts, or other interconnect features. An electrochemical deposition process may be used for the filling of such interconnect features. A semiconductor device with unfilled features may be entered into a plating bath containing various additives as part of the metallization process. Partially fabricated semiconductor devices may be treated prior to plating to improve the plating process.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the present disclosure.

### SUMMARY

Disclosed herein are methods and systems of moisturizing a substrate. In one aspect of the embodiments presented herein a method may be provided, the method including: receiving a substrate in a humidification environment; receiving relative humidity data of the humidification environment from a relative humidity sensor; exposing an active surface of the substrate in the humidification environment to water vapor under conditions based on the relative humidity data, whereby the active surface of the substrate may be humidified without substantially forming condensed water on the active surface; removing the substrate from the humidification environment; and electroplating a material onto the active surface of the substrate. In some embodiments, the method further includes pre-treating the substrate to reduce a metal oxide layer on the surface of the substrate. In some embodiments, pre-treating the substrate reduces the substrate moisture. In some embodiments, pre-treating the substrate includes exposing the substrate to a hydrogen plasma. In various embodiments, pre-treating the substrate includes annealing the substrate in the present of hydrogen. In some embodiments, pre-treating the substrate includes containing the substrate in a front opening, unified pod (FOUP) with nitrogen. In some embodiments, receiving the substrate in the humidification environment may be performed at atmospheric pressure.

In some embodiments, the method further includes reducing pressure in the humidification environment prior to exposing the active surface of the substrate in the humidification environment to water vapor. In various implementations, the pressure in the humidification environment prior to exposing the active surface of the substrate in the humidification environment to water vapor may be between about 0 and about 100 Torr. In some embodiments, receiving the substrate in the humidification environment may be performed at a pressure between about 0 and about 15 Torr. In some embodiments, the conditions under which the active surface of the substrate may be exposed to the humidification environment include exposing the active surface to the humidification environment at a temperature between about 5 to about 95° C. In some embodiments, the humidification environment includes one or more sensors from the group consisting of: a pressure sensor and a substrate temperature sensor. In various embodiments, the conditions under which the active surface of the substrate may be exposed to the humidification environment may be additionally based on data collected from the one or more sensors. In some embodiments, the conditions under which the active surface of the substrate may be exposed to the humidification environment include delivering water vapor to the humidification environment. In some embodiments, the composition of the water vapor may be less than 10 ppm dissolved oxygen.

In some embodiments, the pressure of the humidification environment prior to delivering water vapor may be between about 5 and about 100 Torr. In some embodiments, the relative humidity of the humidification environment prior to delivering water vapor may be between about 0 and about 50%. In various embodiments, the temperature of the water vapor may be between about 10° C. and about 100° C. In various embodiments, the flow rate of the water vapor may be between about 0 and about 3 slm. In some embodiments, the duration of delivering water vapor may be between about 0.1 and about 300 seconds. In some embodiments, the relative humidity of the humidification environment after delivering water vapor may be between about 50 and about 99%.

In some embodiments, the conditions under which the active surface of the substrate may be exposed to the humidification environment include a delay time period. In some embodiments, the delay time period may be between about 0 and about 300 seconds. In various embodiments, the conditions under which the active surface of the substrate may be exposed to the humidification environment include reducing pressure in the humidification environment after exposing the active surface of the substrate to water vapor. In some embodiments, reducing pressure in the humidification environment may be achieved via a vacuum pump configured with a throttle valve. In various embodiments, reducing pressure in the humidification environment reduces pressure to between about 0 and about 100 Torr. In some embodiments, reducing pressure in the humidification environment reduces pressure by between about 0 and about 100 Torr. In some embodiments, reducing pressure in the humidification environment may be performed for less than about 100 seconds.

In various embodiments, the method further includes immersing the substrate in an electroplating bath prior to electroplating a material onto the active surface of the substrate. In some embodiments, the humidification environment may be not part of a pretreatment module or an electroplating module. In some embodiments, the humidification environment may be a FOUP. In some embodiments, the humidification environment may be an electroplating module. In some embodiments, the humidification environment may be a transfer module.

In another aspect of the embodiments disclosed herein, an apparatus is provided, the apparatus including: a chamber configured to hold a substrate during a humidification operation; a water vapor delivery line coupled to the chamber; a vacuum line coupled to the chamber; a relative humidity sensor configured to obtain relative humidity data representing relative humidity in the chamber; and a control system configured to: receive relative humidity data, control delivery of water vapor to the chamber via the water vapor line based at least in part on the relative humidity data, and control pressure in the chamber via the vacuum line based at least in part on the relative humidity data. In some embodiments, the vacuum line further comprises a throttle valve, and the control system may be further configured to control pressure in the chamber via the throttle valve. In various embodiments, the apparatus further includes a pressure sensor configured to obtain pressure data representing pressure in the chamber, wherein the control system may be further configured to control pressure in the chamber via the vacuum line additionally based at least in part on the pressure data. In various embodiments, the apparatus further includes a temperature sensor configured to obtain temperature data representing temperature in the chamber, wherein the control system may be further configured to: control delivery of water vapor to the chamber via the water vapor line based at least in part on the temperature data, and control pressure in the chamber via the vacuum line based at least in part on temperature data. In some embodiments, the chamber interfaces with a FOUP. In various embodiments, the chamber interfaces with a pretreatment module. In some embodiments, the chamber interfaces with an electroplating module.

In another aspect of the embodiments herein, a method is provided, the method including: receiving a substrate in a humidification environment, wherein the pressure of the humidification environment while receiving the substrate may be about atmospheric pressure; reducing pressure in the humidification environment; exposing an active surface of the substrate in the humidification environment to water vapor under conditions, whereby the active surface of the substrate may be humidified without substantially forming condensed water on the active surface; removing the substrate from the humidification environment; and electroplating a material onto the active surface of the substrate.

These and other features of the disclosed embodiments will be described in detail below with reference to the associated drawings.

### BRIEF DESCRIPTION OF DRAWINGS

FIG. 1 presents illustrations of defects maps as a function of pump down time.

FIG. 2 presents illustrations of defect maps based on the starting pressure of vapor delivery.

FIG. 3 presents a process flow chart of one example embodiment.

FIG. 4 presents a schematic diagram of an example system for performing embodiments herein.

FIG. 5 presents another process flow chart of one example embodiment.

FIG. 6 presents another schematic diagram of an example system for performing embodiments herein.

### DETAILED DESCRIPTION

### Introduction and Context

Fabrication of electrically conductive structures in semiconductor devices involves depositing metal lines and vias within recessed features. The features (vias and trenches) may be electrochemically filled with target metal through an electrochemical deposition process by plating onto an active surface of the substrate, e.g., a seed layer or diffusion barrier layer. The active surface may be previously deposited by physical vapor deposition (PVD), chemical vapor deposition (CVD), atomic layer deposition (ALD), or a similar process.

A factor that can affect the performance of an electrochemical deposition process is oxidation of the surface metal. Oxidation can have various negative effects, including increasing resistivity, affecting organic additive behavior within the electroplating bath, dissolution of the seed layer in the electroplating bath, void formation in electrofilled features, and increased non-uniformity of the subsequent electrochemical deposition. Generally, it is difficult to prevent oxidation of a seed layer, and thus various methods are employed to reduce the formation of an oxide layer or reduce the metal oxide. Some methods to control oxidation include containing the wafers in a N₂ rich environment to prevent oxidation. Some methods to reduce the metal oxide back to metal involve a pre-anneal treatment in H₂ or a hydrogen plasma treatment. Examples of dry pretreatments that may be employed prior to electroplating are presented in U.S. Pat. No. 9,070,750, issued Jun. 30, 2015, U.S. Pat. No. 9,865,501, issued Jan. 9, 2018, U.S. Pat.Application Publication No. 20150299886, published Oct. 22, 2015, U.S. Pat. Application Publication No. 20150376792, published Dec. 31, 2015, and U.S. Pat. Application No. 62/664,938, filed Apr. 30, 2018, each of which is incorporated herein by reference in its entirety.

Pre-treatments, particularly dry pre-treatments, to control oxidation of the seed layer sometimes decrease the wettability of the substrate surface, which is undesirable. Without proper wetting, air bubbles may stick to the wafer surface in certain areas during entry of the substrate into a plating bath, and the electrodeposition thereafter may be affected by an electrical discontinuity. The end result is missing plating in these areas. These resulting defects are usually called “missing metal” defects and can be “killer” defects to active devices on the wafer. In particular, low wettability of the substrate can lead to missing metal defects and voids.

Disclosed herein are methods and apparatus to treat wafers that potentially have poor wettability, sometimes as a result of other process steps prior to plating, to improve wetting during wafer immersion into the plating bath and improve performance during an electrochemical plating process onto the wafer. Wetting is improved by moisturizing an incoming substrate in a controlled relative humidity environment. Moisturization of the surface layer involves forming an adsorbed water vapor layer or related species for wettability improvement but avoiding condensation that could corrode the seed. Further discussion of moisturization may be found in U.S. Pat. Application No. 62/664,938, which is incorporated herein by reference for the purpose of moisturization operations. One potential mechanism of improving wettability of a surface involves forming a hydroxide-containing (mono)layer. Improving wafer wettability generally leads to fewer defects during a subsequent plating operation, which is desirable.

Another potential advantage of improving wafer wettability is increasing the boundaries of a process window for the immersion step of the electrochemical plating process. Generally, the immersion step is tuned for optimal wettability by (1) optimizing the immersion movement speed in the vertical direction and rotation (generally referred to as “entry profile”), (2) the angle of substrate tilt (with respect to horizontal), and (3) reducing the surface tension of the plating solution. While those two approaches had been found to significantly improve wettability, they pose constraints to the plating hardware on the plating apparatus and reduced the process margins that are needed for a high-volume manufacturing environment. The techniques disclosed here may allow for a wider range of entry profiles and plating solutions.

As described herein, a “substrate environment,” “humidification environment,” or “moisturization module” is a location or environment where a substrate is exposed to water vapor. This location or environment may be implemented as any of a variety of modules and/or process chambers. In some embodiments, a humidification environment is a front opening, unified pod (FOUP). In some embodiments, a humidification environment is a transfer module, such as an inbound/outbound loadlock module or a vacuum/atmospheric transfer module. In other embodiments, a humidification environment is connected with a process chamber for pretreating the substrate, such as the pretreatments described above. In some embodiments, the humidification environment is an electrodeposition module. In all cases, the substrate surface is modified by exposure to humidity.

In this description, the term “semiconductor wafer” or “semiconductor substrate,” or simply “substrate” refers to a substrate that has semiconductor material anywhere within its body, and it is understood by one of skill in the art that the semiconductor material does not need to be exposed. The semiconductor substrate may include one or more dielectric and conductive layers formed over the semiconductor material. A wafer used in the semiconductor device industry is typically a circular-shaped semiconductor substrate, which may have a diameter of 200 mm, 300 mm, or 450 mm, for example.

It should be noted that what is described here may be different from processes sometimes referred to as pre-wet processes, which are sometimes used to fill features with water or electroplating solution in order to remove gas pockets within features. For purposes of the substrate humidification processes described herein, certain embodiments conduct such processes in a manner that does not fill features with condensed water. In some cases, condensed water in features undesirably affects a subsequent electrochemical deposition process, causing downstream non-uniformities and defects. This may particularly be the case where the condensed water does not have electroplating solution components such as additives. Generally, it is desirable to moisturize the substrate surface and features without fully filling the features with water that lacks some or all components of an electroplating solution. In certain embodiments, a humification process as described herein may be followed by a pre-wetting process. Examples of pre-wetting processes are described in U.S. Pat. No. 9,455,139, issued Sep. 27, 2016, and incorporated herein by reference in its entirety.

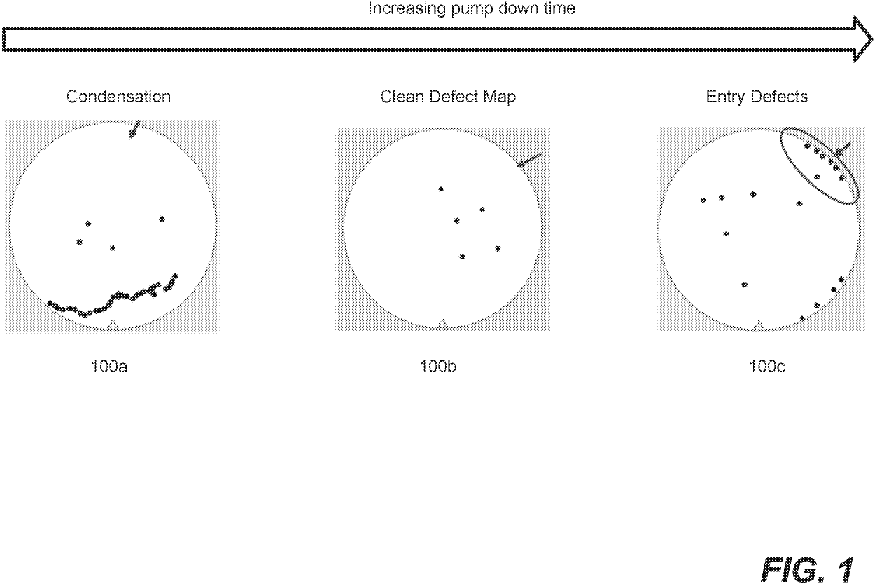

FIG. 1 provides example defect maps 100a-b that illustrate the potential defects from insufficient or excessive moisturization. Defect map 100b is considered a clean defect map, with relatively few defects. Defect map 100a illustrates a line of defects that have been found to be associated with water condensation on the surface. Condensation may fill features with water, inhibiting the plating solution from filling the feature and thus affecting the plating operation. On the opposite end of the spectrum, insufficient moisturization/low wettability may be associated with entry defects. Defect map 100c illustrates entry defects that may result from insufficient moisturization.

Moisturization may be influenced by the substrate temperature, the relative humidity in the chamber where the substrate is moisturized, and the total pressure in the chamber where the substrate is moisturized. Additionally, the process variations under which the substrate is exposed to these conditions may be varied to affect the amount of moisturization of the substrate surface.

### Techniques for Moisturizing a Substrate

In certain embodiments, the substrate moisturization process involves two or three operations, sometimes performed in sequence, to expose the substrate to water vapor (e.g. humidified gas or humidified N₂). At some point in the process, water vapor is delivered to an environment where the substrate is present. As explained herein, the water vapor may be delivered by any of various processes. In some cases, water vapor delivery is accomplished by creating or maintaining a pressure differential between the environment in which the substrate is present and the source of the water vapor, such that there is an associated pressure drop into the humidification environment. In some embodiments, there is a limited time during which the water vapor is delivered to the humidification environment. In some embodiments, various properties of the water vapor as delivered from the source are controlled. For example, the water vapor might not include any condensed water droplets and/or it might be within a particular range of values for relative humidity.

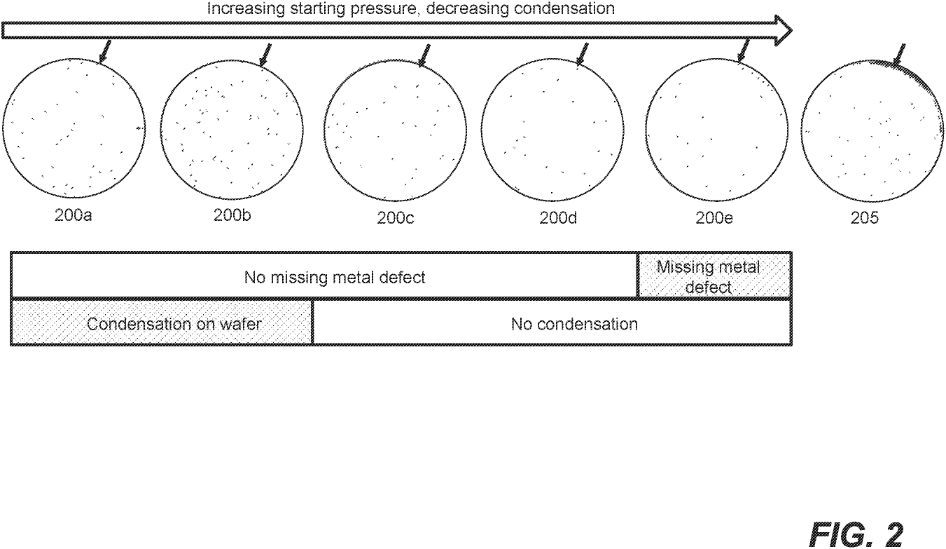

FIG. 2 provides a series of defect maps 200a-e based on the starting pressure of the moisturization module, as well as a defect map 205 where no moisturization process was performed. Vapor delivery generally increases the pressure in the moisturization module from the starting pressure. Defect map 200e and 205 show missing metal defects at the edge of the substrate (the arrows indicates the leading edge into the plating solution). For defect map 200e, while the moisturization process inhibited missing metal defects in comparison to no moisturization process, the starting pressure was too high to sufficiently moisturize the substrate, causing some missing metal defects.

Conversely, for defect maps 200a-d, there were no missing metal defects, but at too low a starting pressure condensation occurred, as shown by defect maps 200a and 200b. Defect maps 200c and 200d represent good defect maps and suggest an appropriate starting pressure of the vapor delivery operation.

Another operation associated with moisturizing a substrate surface may involve a delay or waiting period, during which the substrate surface remains exposed to the water vapor that was just delivered to the humidification environment. The delay/exposure period may allow water to continue to adsorb onto or otherwise modify the surface of the wafer. If the delay time is too short, less water vapor will be adsorbed onto the surface of the substrate, and consequently more defects may arise during electroplating. Conversely, if the delay time is too long, process throughput may be reduced.

Yet another operation associated with moisturizing a substrate surface is an optional “pump down” process, where the pressure in the humidification environment is reduced. This operation may remove condensed water from the substrate surface. In certain embodiments, the pump down process is not performed. In such embodiments, the initial pressure in the environment where the substrate is moisturized may be provided at a relatively higher pressure than in alternative processes where a pump down step is performed.

Returning to FIG. 1, defect maps 100a-c show that substrate defects can be a function of the pump down time. With a low pump down time, water may condense onto the substrate surface, which may cause undesirable defects as shown in defect map 100a. Conversely, if the pump down time is too long, the substrate will lose the moisture delivered during the vapor delivery operation, which may result in poor wettability and entry defects as shown in defect map 100c. In some implementations, a pump down operation will result in neither condensation defects nor entry defects, such as defect map 100b.

In addition to the above, the temperature of the substrate may also affect moisturization performance. Relatively lower temperature substrates may have better adsorption of water vapor on the seed layer. Thus, in some embodiments it is desirable to conduct moisturization at a relatively low temperature. The substrate temperature may be brought to a defined temperature prior to or during a moisturization process.

To achieve well controlled moisturization of a substrate, various sensors may be used, such as pressure manometers, relative humidity sensors, and temperature sensors. In some embodiments, a throttle valve is added to a vacuum pump system connected to the humidification environment to enable more advanced control of the pump rate based on pressure manometer readings. Based on real time pressure and relative humidity reading, various process parameters including (but not limited to) water vapor dispense flowrate, vapor dispense time, inert gas flowrate, inert gas dispense time, pump rate, and pump time are controlled to create a specific environment for moisturizing a wafer. Note that these parameter values need not be static, but rather can be dynamically adjusted in response to sensor readings such as pressure or relative humidity, such that an incoming seed layer on a substrate is moisturized to the right degree to form an appropriate layer hydroxide. The use of sensors to provide real-time feedback may allow for consistent control of the environment that wafers get exposed to, increasing wafer-to-wafer consistency in high volume manufacturing environments.

In certain embodiments, a throttle valve is used to increase or control pressure within the moisturization module. A throttle valve may be added to the vacuum pump system of a module to more finely modulate the pressure in the module during, for example, a vapor delivery operation. In some embodiments, a throttle valve may be used to maintain a target pressure in the moisturization module during a vapor delivery operation. The throttle valve may also be useful during an optional pump down step to provide better control of the change in pressure during the pump down operation.

### High Pressure Embodiments

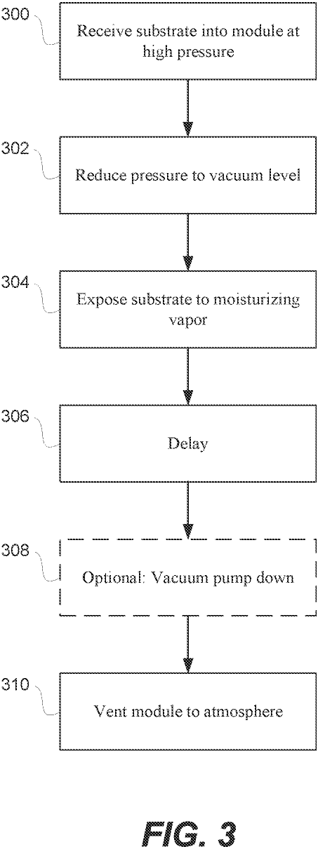

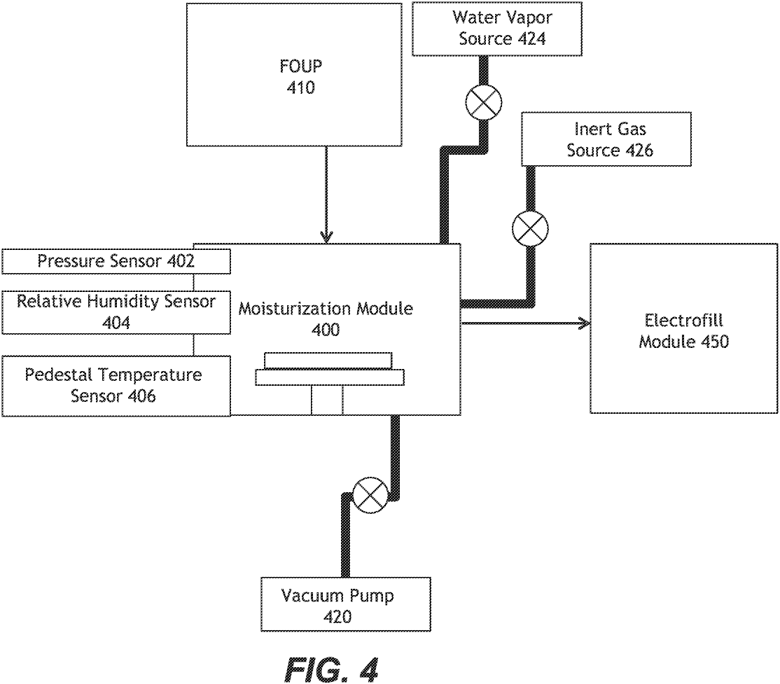

FIGS. 3 and 4 provide a process flowchart for moisturizing a substrate and an example system for moisturizing a substrate, respectively. FIG. 3 provides a process flowchart that may be used when a substrate is provided to a moisturization module at high pressure, such as in the system shown in FIG. 4. In an operation 300, a substrate is received into the moisturization module. In certain embodiments, the module is at a higher pressure, e.g. atmospheric pressure, as the substrate is received from, e.g., another module or storage that is at lower pressure than the moisturization module itself. Next, in an operation 302, the pressure in the moisturization module is reduced in pressure to, e.g., a vacuum level. Then, in an operation 304, the substrate is exposed to water vapor. Operation 304 is a vapor delivery operation, where water vapor is delivered at a higher pressure than the pressure in the module. In some embodiments, a vacuum pump is used to maintain a target pressure of the module while delivering the water vapor.

Following operation 304, an operation 306 is a delay operation to allow for moisturization of the substrate surface. In some embodiments, vapor delivery and/or vacuum pumping is suspended during the delay operation. As depicted in an operation 308, after the delay operation, the moisturization module is optionally pumped down. A vacuum pump may be used to reduce pressure in the module. Finally, in an operation 310, the module is vented to atmosphere. Afterwards, the substrate may be transferred to an electroplating chamber for filling recessed features of the substrate with material.

The following sections provide greater detail on each operation, above.

### Receiving Substrate Into Module at High Pressure

In operation 300, above, a substrate is received into a moisturization module at high pressure. In some embodiments, high pressure refers to a pressure that is higher than the pressure in a prior process chamber, for example a pretreatment module, which may be operated at sub-atmospheric pressures, typically in vacuum. In certain embodiments high pressure is atmospheric pressure. In some embodiments, the substrate may have been previously processed to pretreat the substrate in order to reduce or remove a metal oxide layer. In other embodiments, the substrate may be processed without pretreatment. In some embodiments, the temperature of the substrate is between about 5° C. and about 90° C., or about ambient temperature. In some embodiments, the relative humidity of the moisturization module is between about 0 and about 50% prior to vapor delivery.

### Reduce Pressure to Vacuum Level

In operation 302, above, the pressure in the moisturization module is reduced to a vacuum level. The pressure may be between about 5 and about 100 Torr after operation 302. This operation may take about 0 to about 100 seconds. A lower pressure humidification environment is generally preferable for a moisturization operation, as it reduces the risk of condensation on the substrate.

### Vapor Delivery

In operation 304, above water vapor is delivered to the moisturization module. In some embodiments, the water vapor is a humidified gas. The composition of the water vapor may be at least about 99%, at least about 99.9%, or at least about 99.99% pure water. In some embodiments, the water vapor has a dissolved oxygen content of less than about 10 ppm. In some embodiments, a water vapor dispense flowrate is between about 0 and about 3 slm (standard liters per minute). In some embodiments, a temperature of the water vapor may be in a range from about 20° C. to about 100° C. In some embodiments, a vapor dispense time is between about 0.1 second and about 300 seconds. In some embodiments, a gas is co-flowed with water vapor, for example an inert gas, e.g., N₂, He, or Ar. In some embodiments, the gas vent flowrate is between about 0 and about 10 slm. In some embodiments, the gas vent dispense time is between about 0.1 second and about 300 seconds. In some embodiments, the starting pressure of the vapor delivery is between about 5 torr and about 100 torr. In some embodiments, a vacuum pump is used to counter-balance the increasing pressure in the module due to the vapor delivery. At the conclusion of operation 304, the relative humidity of the moisturization module may be between about 50 and about 99%.

### Delay

In operation 306, above, a delay time occurs to allow for moisturization of the substrate. During the delay period, water vapor is not delivered to the humidification environment, nor is a vacuum drawn. The duration of the delay period may be between about 0 and about 300 seconds.

### Optional Pump Down

In operation 308, above, an optional pump down step reduces pressure in the moisturization module. In some embodiments, a pump rate is between about 1 and about 100 m³/hr, and a pump time is between about 0 and about 300 seconds. In some embodiments, the pressure is reduced by about 0 to about 100 Torr during the pump down step. In some embodiments, the pressure is reduced to a level of about 0 and about 100 Torr after the pump down step.

### Vent Module to Atmosphere

In operation 310, above, the moisturization module is vented to atmosphere. In some embodiments, venting to atmosphere includes flowing a non-reactive gas, e.g., N₂, He, and/or Ar into the moisturization module until the moisturization module reaches atmospheric pressure.

FIG. 4 illustrates a system where a substrate comes into a moisturization module 400 at a high pressure, e.g. atmospheric pressure, from a FOUP 410. The moisturization module 400 may have a pressure sensor 402, a relative humidity sensor 404, and/or a temperature sensor 406. Each sensor may provide data that is used to control the humidification process, such as the pressure or duration of the vapor delivery, the duration of the delay, and the magnitude and/or duration of a pump down. The moisturization module 400 may also be connected to a water vapor source 424, an inert gas source 426 and a vacuum pump 420. The water vapor source 424 may be used to provide water vapor to the moisturization module during a vapor delivery operation. The inert gas source may be used to vent the moisturization module, e.g., vent to atmospheric pressure. Vacuum pump 420 may be used to maintain pressure during the vapor delivery process, as well as for optional pump down operations. In some embodiments, the vacuum pump 420 includes a throttle valve as discussed elsewhere herein. FIG. 4 also illustrates an electrofill module 450, which a substrate may be provided to for electroplating after a moisturization operation performed in the moisturization module 400.

The system of FIG. 4 may be used to carry out the process flow shown in FIG. 3, above. For example, during operation 300, a substrate may move from the FOUP 410 into the Moisturization Module 400. During operation 302, vacuum pump 420 may be used to reduce the pressure in the moisturization module 400. In some embodiments, the pressure sensor 402 provides data indicative of the pressure of the moisturization module 400, allowing the vacuum pump 420 to more accurately reduce the pressure in the moisturization module 400.

During operation 304, water vapor may be delivered via water vapor source 424. In some embodiments, water vapor is a composition containing water vapor and another gas, such as N₂. In such embodiments, water vapor source 424 may include multiple sources, each providing a component of the composition, or the composition may be provided via a single line. In some embodiments, vacuum pump 420 may be run during operation 304 to counterbalance the addition of water vapor into the moisturization module 420 and maintain a specific pressure. In such embodiments, a throttle valve may be used to control the vacuum pump to modulate and provide finer control of the vacuum flow rate. In some embodiments, one or more of the pressure sensor 402, relative humidity sensor 404, and pedestal temperature sensor 406 may provide data that is used to control the delivery of water vapor and the exhaust by the vacuum pump. For example, the relative humidity sensor and pressure sensor may be used to control the flow of water vapor to the moisturization module and exhaust by the vacuum pump until specific pressure and relative humidity values are reached.

During operation 306, the moisturization module 400 may sit idle to allow for moisturization of the substrate. In some embodiments, water vapor is neither delivered to, nor does the vacuum pump exhaust from, the moisturization module.

During operation 308, the vacuum pump 420 may be used to reduce pressure in the moisturization module 400. In some embodiments, the pressure sensor 402 provides data that is used to control the vacuum pump 420.

In operation 310, an inert gas may be flowed into the moisturization module 400 until atmospheric pressure is reached. This may be from a line that is a part of the water vapor source 424, or a separate line (not shown). In some embodiments, water vapor is not flowed into the moisturization module 400 during operation 310. Following the vent to atmosphere, the substrate may be moved from the moisturization module 400 to the electrofill module 450 by various methods and apparatuses (not shown).

### Low Pressure Embodiments

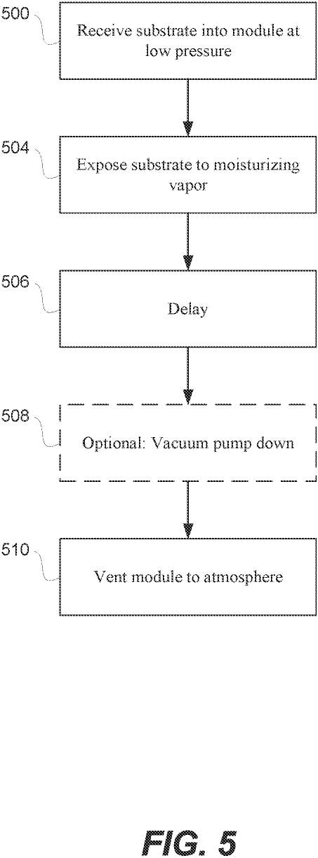

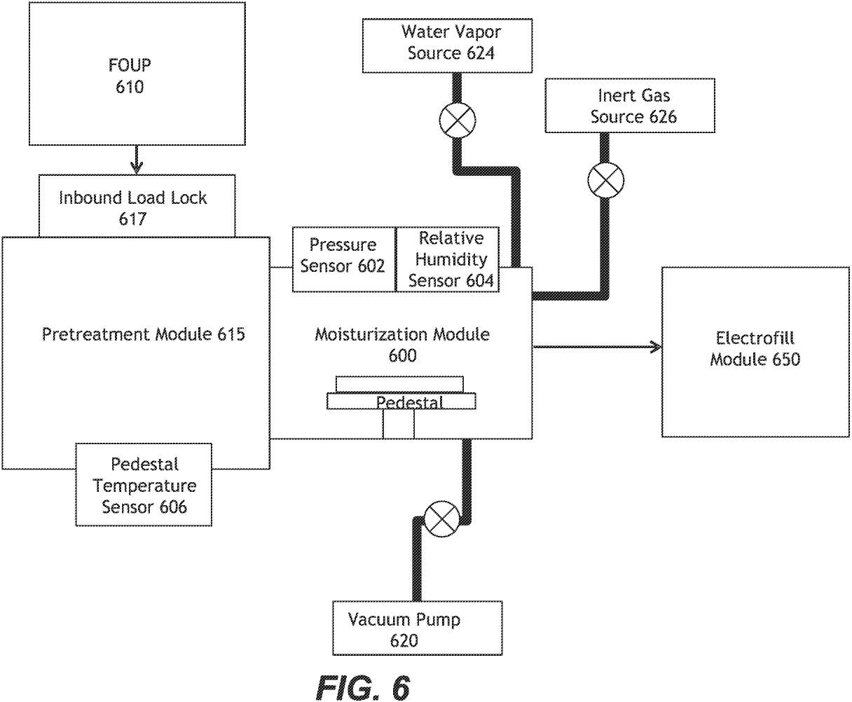

An alternative implementation of the techniques discussed herein involve the substrate being received into a moisturization module at low pressure, e.g. vacuum. FIGS. 5 and 6 provide a process flowchart for moisturizing a substrate and an example system for moisturizing a substrate, respectively. FIG. 5 provides a process flowchart that may be used when a substrate is provided to a moisturization module at low pressure, such as in the system shown in FIG. 6. In operation 500 a substrate is received into the moisturization module at a low pressure. In some embodiments the moisturization module acts as an outbound load lock from a pretreatment module that performs operations in vacuum. In such instances, the module may already be at a vacuum pressure and the substrate may be at an elevated temperature. Then, in operation 504, the substrate is exposed to water vapor at a higher pressure than the pressure in the module. In some embodiments, a vacuum pump is used to maintain a target pressure of the module while delivering the water vapor.

Following operation 504, operation 506 is a delay operation to allow for moisturization of the substrate surface. In some embodiments, neither vapor delivery nor vacuum pumping occurs during the delay operation. Operation 508 is an optional operation to pump down the module. A vacuum pump is used to reduce pressure in the module. Finally, in operation 510, the module is vented to atmosphere. Afterwards, the substrate may be transferred to an electroplating chamber for filling recessed features of the substrate with material.

Operations 504-510 may be substantially similar to operations 304-310, described above. Notably, there is no pressure reduction operation prior to vapor delivery, as the substrate enters the moisturization module at vacuum. In some embodiments, low pressure means the pressure of the moisturization module is the same as the pressure in an immediately prior module, e.g. a pretreatment module. In some embodiments, low pressure is a pressure between about 0 and about 15 Torr. In some embodiments, the temperature of the substrate when it enters the moisturization module is between about 5° C. and about 90° C.

FIG. 6 illustrates a system where a substrate comes into a moisturization module 600 at a low pressure, e.g. vacuum pressure. The moisturization module may be connected with another module that is in vacuum, e.g., pretreatment module 615. The pretreatment module 615 may be used to perform various pretreatments as discussed above, such as annealing treatments or hydrogen plasma treatments. The pretreatment module 615 may receive substrates from a FOUP 610 via an inbound load lock 617. Inbound load lock 617 may be used to transfer the substrate into the low-pressure environment of the pretreatment module. In some implementations, the pretreatment module has a temperature sensor 606, while in other embodiments the temperature sensor may be in the moisturization module 600. The moisturization module 600 may have a pressure sensor 602 and a relative humidity sensor 604. Each sensor may provide data that is used to control the humidification process, such as the pressure or duration of the vapor delivery, the duration of the delay, and the magnitude and/or duration of a pump down, amongst others. The moisturization module 600 may also be connected to a water vapor source 626, an inert gas source 626, and a vacuum pump 620. The water vapor source 624 may be used to provide water vapor to the moisturization module during a vapor delivery operation. The inert gas source may be used to vent the moisturization module, e.g., vent to atmospheric pressure. Vacuum pump 620 may be used to maintain pressure during the vapor delivery process, as well as for optional pump down operations. In some embodiments, the vacuum pump 620 includes a throttle valve. FIG. 6 also provides an Electrofill Module 650, to which a substrate may be provided for electroplating after a moisturization operation performed in the moisturization module 600.

The system shown in FIG. 6 may be used to moisturize a substrate in a similar manner as the system of FIG. 4. However, in some embodiments, the substrate comes into the moisturization module 600 from a pretreatment module 615, rather than a FOUP, such as FOUP 610. Furthermore, the temperature of the substrate may be determined by pressure sensor 606 within the pretreatment module 615, rather than from within moisturization module 600.

### Apparatus

The techniques discussed herein may be performed in various modules or process chambers, including modules and systems similar to those shown in FIGS. 4 and 6. In some implementations, the modules of FIGS. 4 and 6 may include a controller (not shown). The controller may be connected to and control any one or more of pressure sensors, relative humidity sensors, temperature sensors, water vapor sources, inert gas sources, and vacuum pumps (including the optional throttle valve). In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a moisturization module, a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### Conclusion

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method, comprising:
receiving a substrate in a humidification environment;
receiving relative humidity data of the humidification environment from a relative humidity sensor;
exposing an active surface of the substrate in the humidification environment to water vapor under conditions based on the relative humidity data, whereby the active surface of the substrate is humidified without substantially forming condensed water on the active surface;
removing the substrate from the humidification environment; and
electroplating a material onto the active surface of the substrate.

2. The method of claim 1, further comprising pre-treating the substrate to reduce a metal oxide layer on the surface of the substrate.

3. The method of claim 2, wherein pre-treating the substrate reduces the substrate moisture.

4. The method of claim 2, wherein pre-treating the substrate includes exposing the substrate to a hydrogen plasma.

5. The method of claim 2, wherein pre-treating the substrate includes annealing the substrate in the presence of hydrogen.

6. The method of claim 2, wherein pre-treating the substrate includes containing the substrate in a front opening, unified pod (FOUP) with nitrogen.

7. The method of claim 1, wherein receiving the substrate in the humidification environment is performed at atmospheric pressure.

8. The method of claim 7, further comprising reducing pressure in the humidification environment prior to exposing the active surface of the substrate in the humidification environment to water vapor.

9. The method of claim 8, wherein the pressure in the humidification environment prior to exposing the active surface of the substrate in the humidification environment to water vapor is between about 0 and about 100 Torr.

10. The method of claim 1, wherein receiving the substrate in the humidification environment is performed at a pressure between about 0 and about 15 Torr.

11. The method of claim 1, wherein the conditions under which the active surface of the substrate is exposed to the humidification environment include exposing the active surface to the humidification environment at a temperature between about 5 to about 95° C.

12. The method of claim 1, wherein the humidification environment includes one or more sensors from the group consisting of: a pressure sensor and a substrate temperature sensor.

13. The method of claim 12, wherein the conditions under which the active surface of the substrate is exposed to the humidification environment is additionally based on data collected from the one or more sensors.

14. The method of claim 1, wherein the conditions under which the active surface of the substrate is exposed to the humidification environment include delivering water vapor to the humidification environment.

15. The method of claim 14, wherein the composition of the water vapor is less than about 10 ppm dissolved oxygen.

16. The method of claim 14, wherein the pressure of the humidification environment prior to delivering water vapor is between about 5 and about 100 Torr.

17. The method of claim 14, wherein the relative humidity of the humidification environment prior to delivering water vapor is between about 0 and about 50%.

18. The method of claim 14, wherein the temperature of the water vapor is between about 10° C. and about 100° C.

19. The method of claim 14, wherein delivering water vapor is performed at a flow rate between about 0 and about 3 slm.

20. The method of claim 14, wherein the duration of delivering water vapor is between about 0.1 and about 300 seconds.

21. The method of claim 14, wherein the relative humidity of the humidification environment after delivering water vapor is between about 50 and about 99%.

22. The method of claim 1, wherein the conditions under which the active surface of the substrate is exposed to the humidification environment include a delay time period.

23. The method of claim 22, wherein the delay time period is between about 0 and about 300 seconds.

24. The method of claim 1, wherein the conditions under which the active surface of the substrate is exposed to the humidification environment include reducing pressure in the humidification environment after exposing the active surface of the substrate to water vapor.

25. (canceled)

26. The method of claim 24, wherein reducing pressure in the humidification environment reduces pressure to between about 0 and about 100 Torr.

27. The method of claim 24, wherein reducing pressure in the humidification environment reduces pressure by between about 0 and about 100 Torr.

28. (canceled)

29. The method of claim 1, further comprising immersing the substrate in an electroplating bath prior to electroplating a material onto the active surface of the substrate.

30. (canceled)

31. (canceled)

32. (canceled)

33. (canceled)

34. An apparatus, comprising:
a chamber configured to hold a substrate during a humidification operation;
a water vapor delivery line coupled to the chamber;
a vacuum line coupled to the chamber;
a relative humidity sensor configured to obtain relative humidity data representing relative humidity in the chamber; and
a control system configured to:
receive relative humidity data,
control delivery of water vapor to the chamber via the water vapor delivery line based
at least in part on the relative humidity data, and
control pressure in the chamber via the vacuum line based at least in part on the relative humidity data.

35. The apparatus of claim 34, wherein the vacuum line further comprises a throttle valve, and the control system is further configured to control pressure in the chamber via the throttle valve.

36. The apparatus of claim 34, further comprising a pressure sensor configured to obtain pressure data representing pressure in the chamber, wherein the control system is further configured to control pressure in the chamber via the vacuum line additionally based at least in part on the pressure data.

37. The apparatus of claim 34, further comprising a temperature sensor configured to obtain temperature data representing temperature in the chamber, wherein the control system is further configured to:
control delivery of water vapor to the chamber via the water vapor line based at least in part on the temperature data, and
control pressure in the chamber via the vacuum line based at least in part on temperature data.

38. The apparatus of claim 34, wherein the chamber interfaces with a FOUP.

39. The apparatus of claim 34, wherein the chamber interfaces with a pretreatment module.

40. The apparatus of claim 34, wherein the chamber interfaces with an electroplating module.

41. A method, comprising:
receiving a substrate in a humidification environment, wherein the pressure of the humidification environment while receiving the substrate is about atmospheric pressure;
reducing pressure in the humidification environment;
exposing an active surface of the substrate in the humidification environment to water vapor under conditions, whereby the active surface of the substrate is humidified without substantially forming condensed water on the active surface;
removing the substrate from the humidification environment; and
electroplating a material onto the active surface of the substrate.
